(19) United States
(12) Patent Application Publication
(10) Pub. No.: US 2010/0236617 A1
(43) Pub. Date: Sep. 23, 2010

(54) Stacked Structure Solar Cell Having Backside Conductive Contacts

(75) Inventor: Sungsoo Yi, Sunnyvale, CA (US)

Correspondence Address: Vierra Magen Marcus & DeNiro LLP, 575 Market Street, Suite 2500, San Francisco, CA, 94105, US

(73) Assignee: SUNDIODE INC., Sunnyvale, CA (US)

(21) Appl. No.: 12/408,533

(22) Filed: Mar. 20, 2009

(51) Int. Cl. H01L 31/00; H01L 21/00

(52) U.S. Cl. 136/256; 438/98; 257/E21.002

(57) ABSTRACT

A solar cell having back side conductive contacts and method for forming the solar cell is provided. One embodiment is a solar cell having back side conductive contacts. The solar cell has a first region of a first material having a first conductivity over a front side of a substrate, a second region of a second material conformably on the first material, and a third region of a third material having a second conductivity conformably on the second material. The first region, the second region, and the third region form a structure that generates charge carriers from solar radiation. The solar cell has a first conductive contact and a second conductive contact exposed on the back side of the substrate. The first conductive contact is in electrical contact with the first material and the second conductive contact is in electrical contact with the third material.

### FIELD OF THE INVENTION

The present invention relates to solar cell designs.

### BACKGROUND

Solar-cell technology is currently poised to make significant progress in mass adoption due in part to the looming shortage of traditional energy sources, e.g. crude oil and natural gas, and to the increased awareness of “green-technology” benefits. Solar-cell technology, though capturing “free” energy from the sun, has been expensive with per-watt ownership cost ($/W) far exceeding the cost per watt offered by conventional electric utilities. Recently at $5/W, the pay-off period for a solar panel is as much as 50% of its lifespan, due largely to the expense of the semiconductor materials used.

Semiconductor based solar cells pass solar radiation from a front side of the solar cell through an active region to a back side of the solar cell. Charge carriers are generated due to absorption of photons in the active region. The solar cell has two conductive contacts that are electrically connected to two different regions of the solar cell to allow a circuit to be formed to allow power to be generated based on the charge carrier creation. Typical solar cells have conductive contacts on both the front and rear sides of a solar cell to make electrical contacts to the cell. However, the front conductive contacts impede solar radiation from entering the solar cell, which is detrimental to the solar cell performance.

Silicon based solar cells having all of the conductive contacts on the back side (“back side contact solar cell”) have been proposed. These silicon based solar cells may comprise a monocrystalline silicon wafer. When solar radiation passes through the silicon wafer charge carriers are generated, which is the basis for generating power. Because back-side contact solar cells do not have a front side conductive contact to block incoming solar radiation, back-side contact solar cells have an efficiency advantage over those with front side conductive contacts. However, the monocrystalline silicon wafer may not be as efficient at generating charge carriers from solar radiation as other solar cell designs.

For example, solar cells have been proposed based on group III-V compound semiconductors. Such group III-V compound solar cells may be more efficient than solar cell designs such as those based on a monocrystalline silicon wafer. However, placing all of the conductive contacts on the back side of a group III-V compound multi-junction semiconductor presents challenges. There are challenges when placing back side contacts on other solar cell designs as well.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY

A solar cell having back side conductive contacts and method for forming the solar cell is disclosed. In some embodiments, the solar cell has a stacked structure that generates charge carriers from solar radiation. The stacked structure may be very efficient at generating charge carriers. In some embodiments, the solar cell design is based on compound semiconductors that may include a group III element and a group V element.

One embodiment is a solar cell having back side conductive contacts. The solar cell has a first region of a first material having a first conductivity over a front side of a substrate, a second region of a second material conformably on the first material, and a third region of a third material having a second conductivity conformably on the second material. The first region, the second region, and the third region form a structure that generates charge carriers from solar radiation. The solar cell has a first conductive contact and a second conductive contact exposed on the back side of the substrate. The first conductive contact is in electrical contact with the first material and the second conductive contact is in electrical contact with the third material.

One embodiment is a method for forming a solar cell. The method comprises forming a first region of a first material having a first conductivity over a substrate having a front side and a back side. The first region is formed over the front side of the substrate. A second region of a second material is formed conformably on the first material. A third region of a third material having a second conductivity is formed conformably on the second material. The first region, the second region, and the third region form a structure that generates charge carriers from solar radiation. A first conductive contact is formed such that it is exposed on the back side of the substrate and in electrical contact with the first material. A second conductive contact is formed such that it is exposed on the back side of the substrate and in electrical contact with the third material.

One embodiment is a solar cell having back side conductive contacts and a stacked structure that generates charge carriers from solar radiation. The stacked structure, which resides on the front side of the substrate, includes one or more regions having a first conductivity, one or more active regions, and one or more regions having a second conductivity. The solar cell has a first conductive contact and a second conductive contact exposed on the back side of the substrate. The first conductive contact is in electrical contact with a first of the one or more regions having a first conductivity. The second conductive contact is in electrical contact with a first of the one or more regions having a second conductivity.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A is one embodiment of a solar cell.

FIG. 1B is one embodiment of a mask layer of a solar cell.

FIG. 1C is one embodiment of a mask layer of a solar cell.

FIG. 2 is one embodiment of a process of forming a solar cell having back side contacts.

FIG. 3A, FIG. 3B, FIG. 3C, FIG. 3D, FIG. 3E, FIG. 3F, and FIG. 3G are diagrams depicting stages of forming one embodiment of a solar cell.

FIG. 4 depicts an example of an alternative device structure for use in a solar cell with back side contacts.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

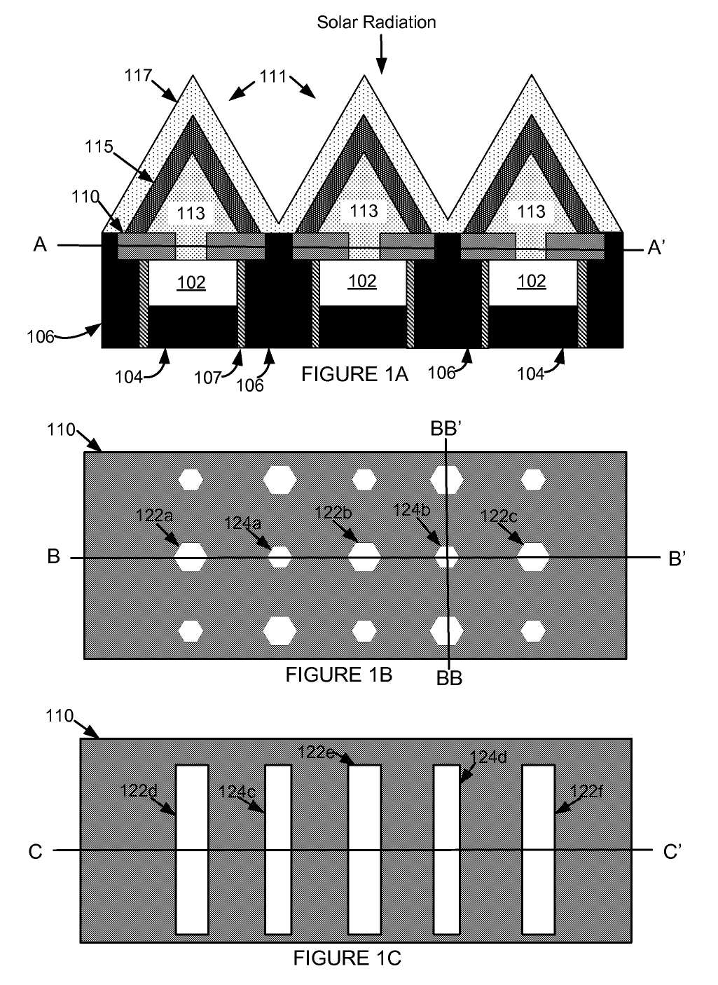

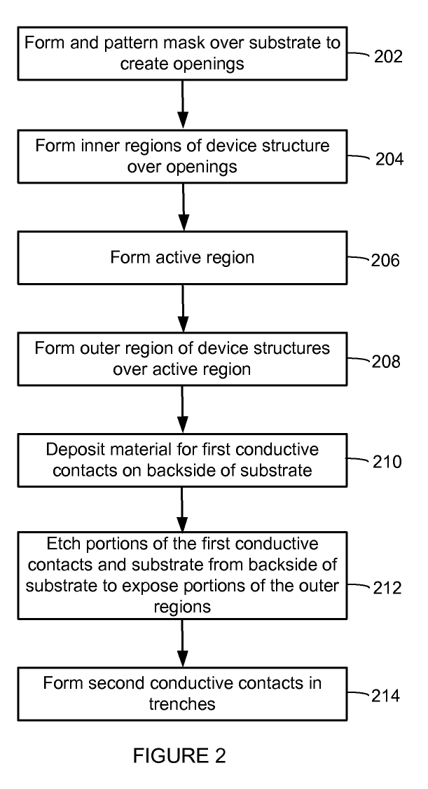

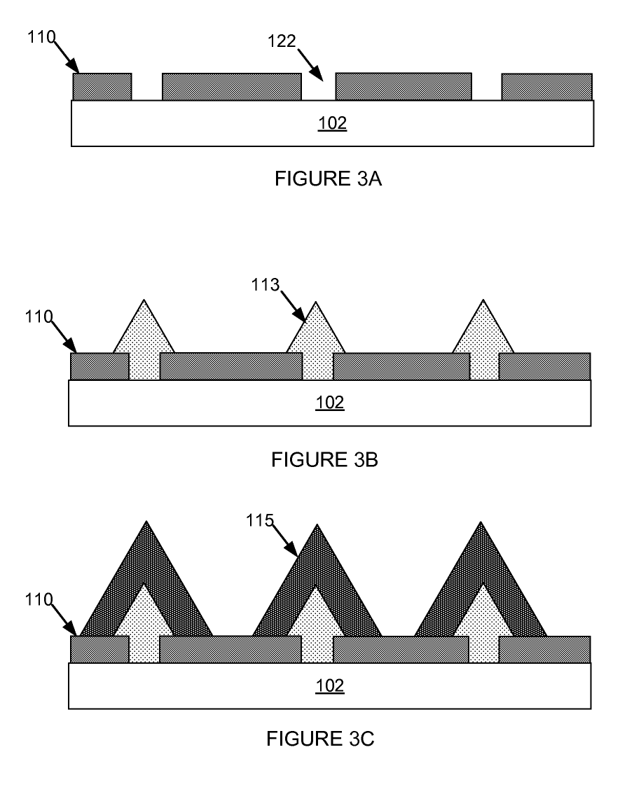

FIG. 1A depicts one embodiment of a solar cell having back side conductive contacts. In general, the solar cell includes device structures 111 that are formed above a substrate 102, first conductive contacts 104, and second conductive contacts 106. The device structures 111 generate charge carriers in response to solar radiation that is admitted from the “front side.” None of the conductive contacts 104, 106 prevent any of the solar radiation from reaching the device structures 111 in this embodiment. The conductive contacts 104, 106 make electrical contacts with the device structures 111 from the “back side” and are exposed on the “back side” to allow the solar cell to be connected to an electrical circuit. It is not required that the conductive contacts 104, 106 make physical contact with the device structures 111. For example, both the conductive contacts 104, 106 may be located on a back side surface of the substrate 102 or may reside in trenches that are formed in the substrate 102. The trenches may go completely through the substrate 102 such that a conductive contact in the trench makes physical contact with a device structure 111, but it is not required that the trench go completely through the substrate 102.

In the embodiment depicted in FIG. 1A, each device structure 111 has an inner region 113, an active region 115, and an outer region 117. Collectively, the inner region 113, active region 115, and outer region 117 form a stacked structure. The inner region 113 may have a first conductivity type (e.g., n-doped), whereas the outer region 117 may have a second conductive type (e.g., p-doped). Note that either the inner region 113 or the outer region 117 may have positive conductivity. Hence, the device structures 111 may be p-i-n or n-i-p devices. The active region 115 may be undoped (intrinsic) and is located between the inner region 113 and the outer region 117. However, the active region 115 may be doped, resulting in either a p-n device or an n-p device. When doped, the active region 115 may be doped with impurity ions having the same conductivity as either the inner region 113 or the outer region 117.

Solar radiation (e.g., photons) enters through the top of the solar cell and may be absorbed in the active region 115. Absorption of a photon promotes an electron to the conduction band. Electrons promoted to a conduction band by the absorption of photons may conduct to the conductive contacts 104, 106. The conductive contacts 104, 106 may be made of a suitable metal, and do not need to be transparent. Hence, all of the conductive contacts 104, 106 can be optimized for high conductance. The conductive contacts 104, 106 may be connected to electrical leads (not depicted in FIG. 1A) to allow the charge carriers to be extracted from the solar cell.

In the embodiment of FIG. 1A, each active region 115 is a conformal layer over an inner region 113. The outer regions 117 form a conformal layer over the active regions 115, and in this embodiment are coalesced. However, it is not a requirement that the outer regions 117 are coalesced. Herein, the portion of the top layer of the device structure 111 that covers a particular active region 115 may be referred to as an outer region 117. Thus, for purposes of discussion the embodiment depicted in FIG. 1A can be considered to have three outer regions 117 whether or not the outer regions 117 are coalesced.

Note that the device structures 111 are not limited to the p-i-n design having a single active region 115. In some embodiments, the device structures 111 form a stack with multiple active layers.

In the embodiment depicted in FIG. 1A, the substrate 102 is an n-type substrate if the inner region 113 is n-doped, but is a p-type substrate if the inner region 113 is p-doped. The substrate 102 may be formed from materials including, but not limited to, silicon, germanium, gallium arsenide, gallium nitride, gallium antimonide, and indium phosphide.

A mask layer 110 having a pattern resides between the device structures 111 and the substrate 102. FIG. 1B depicts one embodiment of a mask layer 110. The mask layer 110 of FIG. 1B is a perspective view along line A-A′ of FIG. 1A. The mask 110 of FIG. 1B has numerous hexagonal openings 122a, 122b, 122c, 124a, 124b. The openings 122, 124 can have a wide variety of shapes such as circles, polygons, etc. The mask 110 may have many different patterns as well. FIG. 1C depicts one embodiment of the mask layer 110 in which the openings 122d, 122e, 122f, 124c, 124d are elongated.

The solar cell of FIG. 1A is a perspective view along line B-B′ of FIG. 1B. The example solar cell of FIG. 1A depicts three device structures 111, which in this example are triangular in shape in a cross section along the line B-B′ in FIG. 1B. Thus, referring to FIG. 1B, each of the openings 122a, 122b, and 122c allow one of the inner regions 113 to make contact with the substrate 102. Each of the openings 124a and 124b allow one or more of the outer regions 117 to make contact with one of the second conductive contacts 106. Note the electrical contact between each of the inner regions 113 and one of the first conductive contacts 104 is made through the substrate 102 in this embodiment. However, a trench could be formed in the substrate 102 to allow direct physical contact between conductive contact 104 and the inner region 113.

The mask 110 in FIG. 1B also has openings above and below line B-B′. There will be device structures 111 along the rows defined by those openings also. Note that the device structures 111 may have many other geometries. For example, it is not required that they be triangular in cross section. Instead the device structures 111 might be hemispherical, rectangular, trapezoidal, or another shape in cross section along line B-B′.

The general shape of the device structures 111 along line BB-BB′ in FIG. 1B may be similar to the shape depicted in FIG. 1A. However, such symmetry is not required. Referring now to the mask 110 in FIG. 1C, the mask 110 may have elongated openings 122d, 122e, 122f, 124c, 124d. In this case the device structures 111 may still be triangular in cross section along line C-C′. However, rather than having several rows of device structures 111 as in FIG. 1B, each device structure 111 may extend over the length of openings 122, 124 in FIG. 1C. Openings 122d, 122e, and 122f each allow one of the inner regions 113 to contact the substrate 102. Openings 124c and 124d allow each the outer regions 117 to make electrical contact with one of the second conductive contacts 106.

The mask 110 or the substrate 110 may be reflective to allow unabsorbed photons to travel back up towards the active regions 115 in the devices 111.

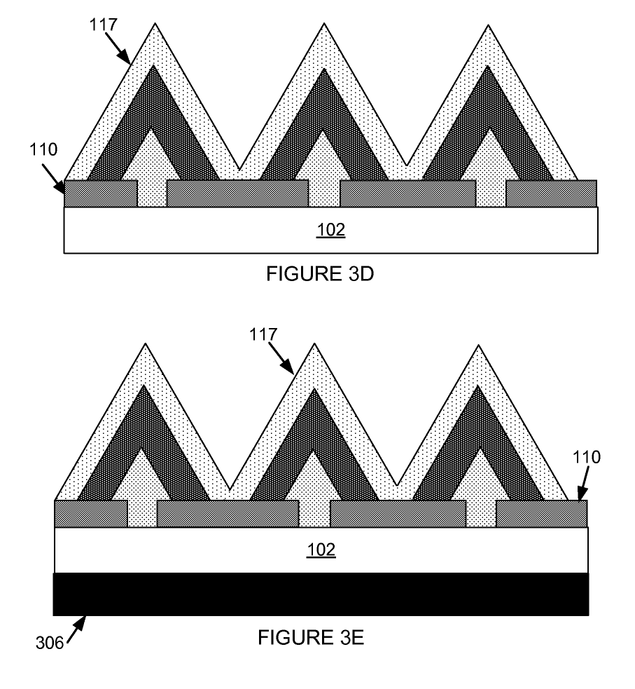

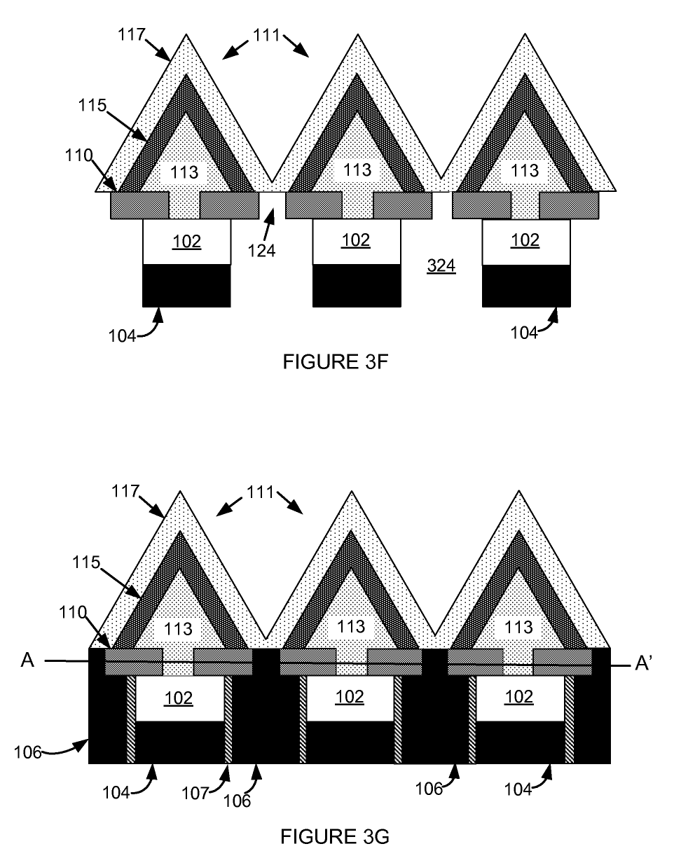

A process flow for forming the solar cell of FIG. 1A will now be discussed referring to the flowchart of FIG. 2. FIGS. 3A-3G show various stages of forming the solar cell and will be referred to when discussing the process flow. FIGS. 3A-3G depict the same perspective as the one in FIG. 1A. In step 202, a masking layer 110 such as SiO₂ or SiNₓ is deposited on a substrate 102 and patterned to create openings 122 that will allow the inner regions 113 of the device structures 111 to make electrical contact to the substrate 102. Openings 124 that allow the outer regions 117 of the device structures 111 to contact the second conductive contacts 106 are not yet formed. Techniques for depositing and etching masks to create openings are known and hence will not be described in detail. The mask 110 may be etched by either wet or dry etching. FIG. 3A depicts results after step 202. In one embodiment, the openings 122 have a width of a few micrometers (μm). However, the openings 122 may be wider or more narrow. The spacing between openings 122 may be on the order of micrometers (μm) or tens of μm. However, the openings 122 may be spaced more widely or more narrowly. Factors that may affect the desired spacing between openings 122 may include the lateral growth rates, thickness and slopes of regions 113, 115, and 117. The number of layers in the device structures 111 may also affect the spacing. The substrate 102 can be either n-type or p-type depending on the device structure (n-i-p or p-i-n). Examples of substrate materials include, but are not limited to, Si, Ge, GaAs, GaN, GaSb, and InP.

In step 204, the inner regions 113 of the device structures 111 are formed. For an n-i-p device structure, n-doped regions are grown selectively in and around the openings 122. For a p-i-n device structure, p-doped regions are grown selectively in and around the openings 122. In one embodiment, the material for the inner region 113 includes a group III element and a group V element. As examples, the material for the inner region 113 may be GaAs, AlGaAs, InGaP, and GaN. FIG. 3B depicts results after step 204 for a case in which a cross section of the inner region 113 has a triangular shape. In one embodiment, the inner regions 113 are grown using selective area epitaxy (SAE). SAE refers to the lateral, spatially controlled growth of epitaxial materials, typically within openings in a mask layer (such as mask 110). SAE extends the dimensional control during growth from a typically planar conformal deposition to the achievement of an arbitrary lateral definition down to the sub-micron level. Growth conditions (e.g., temperature, pressure, precursor flow rates, and group V precursor/group III precursor ratio) may be selected to prevent unwanted deposit on mask layer 110. The cross-sectional shape of materials grown out of openings 122 can be triangular, rectangular, trapezoidal, or hexagonal and are mainly determined by growth conditions. Note that the slope of the sides of the triangle is not limited to any particular angle.

In step 206, the active regions 115 of the device structures 111 are formed. The active regions 115 may be grown over the inner regions 113. In one embodiment, each active region 115 is formed as a conformal layer over one of the inner regions 113. Thus, the active region 115 covers the portions of the inner regions 113 that were exposed. Note that a portion of the active region 115 may extend over a portion of the mask 110 that is not covered by an inner region 113. In one embodiment, the material for the inner region 113 includes a group III element and a group V element. As one example, the material for the inner region 113 may be GaAs, AlGaAs, InGaP, and GaN. It is not a requirement that the active region 115 be formed from the same material as the inner region 113. FIG. 3C depicts results after step 206 for an example with a triangular cross section. Note that the active regions 115 are not coalesced. That is, the active regions 115 do not join together to form a continuous layer on the surface of the mask 110.

In step 208, the outer regions 117 of the device structure 111 are formed over the active regions 115. In one embodiment, each outer region 117 is formed as a conformal layer over one of the active regions 115. Thus, the outer regions 117 cover the portions of the active regions 115 that were exposed. Note that portions of the outer regions 117 extend over portion of the mask 110 that are not covered by the active regions 115. These portions of the mask 110 will later be etched to allow the outer regions 117 to make contact with one of the back side conductive contacts 106.

For an n-i-p device structure, p-doped regions are grown for the outer regions 117. For a p-i-n device structure, n-doped regions are grown. In one embodiment, the material for the outer region 117 includes a group III element and a group V element. As one example, the material for the outer region 117 may be GaAs, AlGaAs, InGaP, and GaN. FIG. 3D depicts results after step 208 for a device 111 having a triangular cross section. Growth conditions for the outer regions 117 may be optimized to enhance lateral growth rate (relative to vertical growth rate). As lateral growth continues, growth fronts meet and form a coalesced, continuous layer. In one embodiment, epitaxial lateral overgrowth (ELO) is used to form the coalescence layer of the outer regions 117. A direct extension of SAE is ELO in which an epilayer is seeded through the openings in the mask layer and grows laterally over the mask layer from the openings.

After step 208, additional processing of the front side may take place, such as forming an anti-reflective layer over the top region 117 to reduce optical losses associated with light reflection on the top surface of the solar cell. The window layer is not depicted so as to not obscure the drawings. Note that the outer region 117 as formed may have a rough, faceted top surface, which may also reduce reflection. However, if desired additional processing may be performed on the outer region 117 to alter the shape.

Next processing continues on the back side of the substrate 102. Techniques for accurately forming features on the backside of the substrate 102 such that they are aligned with features already formed on the front side are known and will not be discussed in detail.

In step 210, the material 306 for the first conductive contacts 104 is deposited across the backside of the substrate 102. The first conductive contacts 104 may be formed from a material such as copper, aluminum, tungsten, nickel, titanium, gold, alloys, etc. While the first conductive contacts 104 are typically a metal, this is not a requirement. Results of step 210 are depicted in FIG. 3E.

In step 212, portions of the material 306 for the first conductive contacts 104, the substrate 102, and the mask 110 are etched. This etching may include multiple steps and creates openings 124 in the mask 110 for the second conductive contacts 106, as well as a trench 324 in the substrate and material 306 for the first contacts 104. The etching step(s) may also form the first conductive contacts 104 from the material 306. Step 212 results in the creation of openings 124 that allow the outer regions 117 of the device structures 111 to contact the second conductive contacts 106. Results of step 212 are depicted in FIG. 3F. Note that the first conductive contacts 104 may be covered by a mask (not depicted in FIG. 3F) at this time, which is not removed until later such that the first conductive contact is protected during later process steps. Note that the size of openings 124 is such that the active region 115 is not exposed to the openings 124.

In step 214, the second conductive contacts 106 are formed. Prior to depositing the material for the second conductive contacts 106 an insulator 107 may be formed in the trench 324 that was formed from etching in step 212. Material for the second conductive contacts 106 is deposited in the openings 124 and the trench 324. Chemical mechanical polishing (CMP) may be performed to remove excess material for the second conductive contacts 106. Results of step 214 are depicted in FIG. 3G.

Note that many variations of the process steps are possible. For example, many different techniques can be used to form the first and second conductive contacts 104, 106 on the back side of the substrate 102. For example, rather than forming a feature by depositing a material and then etching the material, the feature could be formed by forming a trench and then depositing the material in the trench.

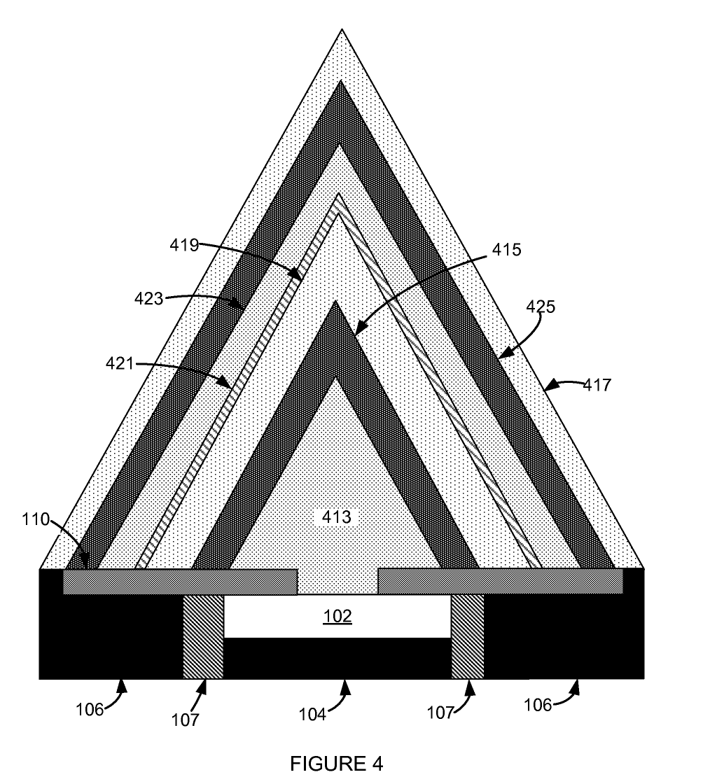

FIG. 4 depicts an example of an alternative device structure for use in a solar cell with back side contacts. The device is a tandem solar cell in this embodiment. The tandem solar cell includes two solar cells joined by a heavily doped, reverse biased tunnel junction layer 421. One solar cell includes inner region 413, active region 415, and region 419. This solar cell may be a p-i-n device, wherein region 413 and 419 are doped with impurity ions of opposite conductivity. For example, region 413 is p-doped and region 419 is n-doped. The other solar cell includes region 423, active region 425, and outer region 417. This solar cell may be a p-i-n device, wherein region 423 and 417 are doped with impurity ions of opposite conductivity. For example, region 423 is p-doped and region 417 is n-doped such that regions 423 and 419 form a pn junction.

The tandem solar cell sits over a substrate 102 such that inner region 413 has an electrical connection to one back side contact 104 and the outer region 417 has an electrical connection to another back side contact 106. The mask layer 110 provides insulation between other parts of the solar cells and the electrical contacts 104, 106 and substrate 102. Insulator 107 provides electrical isolation between contact 104 and 106. There may be many such tandem solar cells in a single solar cell device. The tandem solar cells can be shaped other than triangular.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A solar cell comprising:
a substrate having a front side and a back side;
a first region of a first material having a first conductivity over the front side of the substrate;
a second region of a second material conformably on the first material;
a third region of a third material having a second conductivity conformably on the second material, the first conductivity and second conductivity are opposite from each other, wherein the first region, the second region, and the third region form a structure that generates charge carriers from solar radiation;
a first conductive contact exposed on the back side of the substrate, the first conductive contact is in electrical contact with the first material; and
a second conductive contact exposed on the back side of the substrate, the second conductive contact is in electrical contact with the third material.

2. The solar cell of claim 1, further comprising:
an insulating mask layer over the front side of the substrate, the insulating mask has a first opening, a portion of the first material is in the opening to allow electrical contact to the first conductive contact.

3. The solar cell of claim 2, wherein the substrate is conductive and resides between the first material and the first conductive contact.

4. The solar cell of claim 2, wherein the insulating mask has a second opening that allows electrical contact between the third material and the second conductive contact.

5. The solar cell of claim 4, wherein a portion of the second conductive contact resides in the second opening.

6. The solar cell of claim 1, further comprising:
an insulating mask layer over the front side of the substrate, the insulating mask has a second opening that allows electrical contact between the third material and the second conductive contact.

7. The solar cell of claim 6, wherein a portion of the second conductive contact resides in the second opening.

8. The solar cell of claim 1, wherein the first region, the second region, and the third region are formed from a compound semiconductor having a group III element and a group V element.

9. A method for forming a solar cell, the method comprising:
forming a first region of a first material having a first conductivity over a substrate having a front side and a back side, the first region is formed over the front side;
forming a second region of a second material conformably on the first material;
forming a third region of a third material having a second conductivity conformably on the second material, the first region, the second region, and the third region form a structure that generates charge carriers from solar radiation;
forming a first conductive contact that is exposed on the back side of the substrate and is in electrical contact with the first material; and
forming a second conductive contact that is exposed on the back side of the substrate in electrical contact with the third material.

10. The method for forming a solar cell of claim 9, further comprising:
forming a first opening in an insulating mask layer over the front side of the substrate, a portion of the first material is formed in the first opening to allow electrical contact to the first conductive contact.

11. The method for forming a solar cell of claim 10, wherein the substrate is conductive and resides between the first material and the first conductive contact.

12. The method for forming a solar cell of claim 10, further comprising:
forming a second opening in the insulating mask layer, the second conductive contact is formed in the second opening to allow electrical contact between the third material and the second conductive contact.

13. The method for forming a solar cell of claim 12, wherein the forming a second conductive contact includes forming a portion of the second conductive contact in the second opening.

14. A solar cell comprising:
a substrate having a front side and a back side;
a stacked structure that resides on the front side of the substrate and includes:
one or more regions having a first conductivity;
one or more active regions;
one or more regions having a second conductivity, wherein the stacked structure generates charge carriers from solar radiation;
a first conductive contact exposed on the back side of the substrate, the first conductive contact is in electrical contact with a first of the one or more regions having a first conductivity; and
a second conductive contact exposed on the back side of the substrate, the second conductive contact is in electrical contact with a first of the one or more regions having a second conductivity.

15. The solar cell of claim 14, wherein the stacked structure includes an innermost region and an outermost region, the first region having the first conductivity is the innermost region and the first region having the second conductivity is the outermost region.

16. The solar cell of claim 15, further comprising:
an insulating mask layer over the front side of the substrate, the insulating mask has a first opening, a portion of the innermost region is in the opening to allow electrical contact to the first conductive contact.

17. The solar cell of claim 15, wherein the substrate is conductive and resides between the innermost region and the first conductive contact.

18. The solar cell of claim 15, further comprising:
an insulating mask layer over the front side of the substrate, the insulating mask has a second opening that allows electrical contact between the outermost region and the second conductive contact.

19. The solar cell of claim 18, wherein a portion of the second conductive contact resides in the second opening.

20. The solar cell of claim 14, wherein the one or more regions having a first conductivity are formed from a compound semiconductor having a group III element and a group V element.
